(19) United States
(12) Patent Application Publication
(10) Pub. No.: US 2024/0071856 A1
(43) Pub. Date: Feb. 29, 2024

(54) ELECTRONIC ASSEMBLY HAVING A COOLING FEATURE AND METHODS OF FORMING THEREOF

(71) Applicant: Intel Corporation, Santa Clara, CA (US)

(72) Inventors: Bok Eng CHEAH, Pulau Pinang (MY); Seok Ling LIM, Kulim Kedah (MY); Jenny Shio Yin ONG, Pulau Pinang (MY); Jackson Chung Peng KONG, Pulau Pinang (MY); Kooi Chi OOI, Pulau Pinang (MY)

(21) Appl. No.: 17/895,102

(22) Filed: Aug. 25, 2022

(51) Int. Cl. H01L 23/367; H01L 23/373

(52) U.S. Cl. CPC H01L 23/3675; H01L 23/3736

(57) ABSTRACT

The present disclosure is directed to an electronic assembly and method of forming thereof. The electronic assembly may include a substrate and a first die with first and second opposing surfaces. The first die may be coupled to the substrate at the first surface. At least one first trench may extend partially through the first die from the second surface. A stiffener may be attached to the substrate. The stiffener may have a cavity that accommodates the first die, in which the second surface of the first die faces the stiffener. A thermally conductive layer may be positioned between the stiffener and the first die. The conductive layer at least partially fills the at least one first trench.

### BACKGROUND

In advanced electronic or semiconductor packages, the need to improve thermal management solutions are constant challenges. For example, in a 2.5D packaging architecture, two or more high performance silicon dies are mounted on an interposer to achieve improved performance through higher degree of heterogenous device integration, e.g., central processing unit (CPU), graphic processing unit (GPU), and/or neural processing unit (NPU) or deep learning processor (DLP). However, increased degree of device integration in a compact form factor poses significant challenges related to thermal dissipation especially device hot-spot management to ensure robust device reliability.

Conventional techniques to cope with the increasingly difficult thermal management, especially with multiple chiplets in a disaggregated architecture, include continuous use of oversized thermal interface material (TIM) and heat spreader assembly, and additional copper bumps (e.g., use of dummy bumps to increase density of bumps for more conductive channels) to increase heat spreading on a large surface area. Other advanced device cooling solutions include, for example, immersion cooling, silicon-level micro-channel heat exchangers (MCHEs), or thin-film thermoelectric coolers (TECs) are also being explored to address thermal challenges in advanced packaging. However, the above-mentioned solutions include thermal dissipation efficiency concerns, system footprint and/or form-factor trade-offs, and increased material costs.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity In the following description, various aspects of the present disclosure are described with reference to the following drawings, in which:

FIGS. 1A and 1B show cross-section and top views, respectively, of an exemplary electronic assembly according to an aspect of the present disclosure;

FIGS. 2A and 2B show cross-section and top views, respectively, of another exemplary electronic assembly according to an aspect of the present disclosure;

FIGS. 3A and 3B show cross-section and top views, respectively, of yet another exemplary electronic assembly according to an aspect of the present disclosure;

FIGS. 4A through 4G show exemplary method steps for forming an integrated conductive trench cooling feature in an electronic assembly, according to an aspect of the present disclosure; and

FIG. 5 shows a simplified flow diagram for an exemplary method according to an aspect of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

The present disclosure is directed to an electronic or semiconductor assembly or package that provides an integrated thermally conductive trench cooling feature for improved device thermal management and electrical performance of the electronic assembly containing one or more dies or chips (or chiplets). According to various embodiments, a die may include at least one trench extending partially through the die and a thermally conductive layer positioned in a cavity between a stiffener and the die, in which the conductive layer at least partially fills the at least one trench in the die. The at least one trench may be configured on or adjacent (or around) localized thermal hot spots within the die.

A technical advantage of the present disclosure includes providing enhanced thermal management performance, such as, with the use of localized trench(es) in the chip or die to target power density hotspot(s). The use of the thermally conductive layer (e.g., liquid metal), which at least partially fills the trench, coupled with the stiffener allows for larger surface area, e.g., utilizing the three-dimensional volume of trenches encroaching to one or more dies, for heat dissipation and thus higher efficiency. In the case multiple dies are employed in the assembly, the conductive layer may at least partially fill the trenches in the dies and allow for larger surface area for heat dissipation.

Another technical advantage of the present disclosure includes device miniaturization through integration of package stiffener as part of the thermal management solution and simplification of components required for device cooling. In this regard, the stiffener, including the conductive layer which at least partially fills the at least one trench, may be directly coupled to a heat sink and/or cooling fan for heat dissipation. Accordingly, a separate integrated heat spreader component may be eliminated.

According to various embodiments, the conductive layer, which fills the at least one trench, may be coupled to a reference voltage. For example, the conductive layer may be coupled a ground reference voltage (Vss). An additional technical advantage of the present disclosure includes enhanced electrical performance due to electromagnetic shielding from undesired coupling with sensitive circuitry such as input clock signal from radio-frequency (RF) noises through the configuration of the conductive layer, which fills the at least one trench, to a ground reference voltage (Vss). In another example, for certain implementations, the conductive layer may be coupled a power supply voltage (Vcc).

To more readily understand and put into practical effect the present cooling feature of the electronic assembly and methods, which may be used for electronic assemblies, particular aspects will now be described by way of examples provided in the drawings that are not intended as limitations. The advantages and features of the aspects herein disclosed will be apparent through reference to the following descriptions relating to the accompanying drawings. Furthermore, it is to be understood that the features of the various aspects described herein are not mutually exclusive and can exist in various combinations and permutations. For the sake of brevity, duplicate descriptions of features and properties may be omitted.

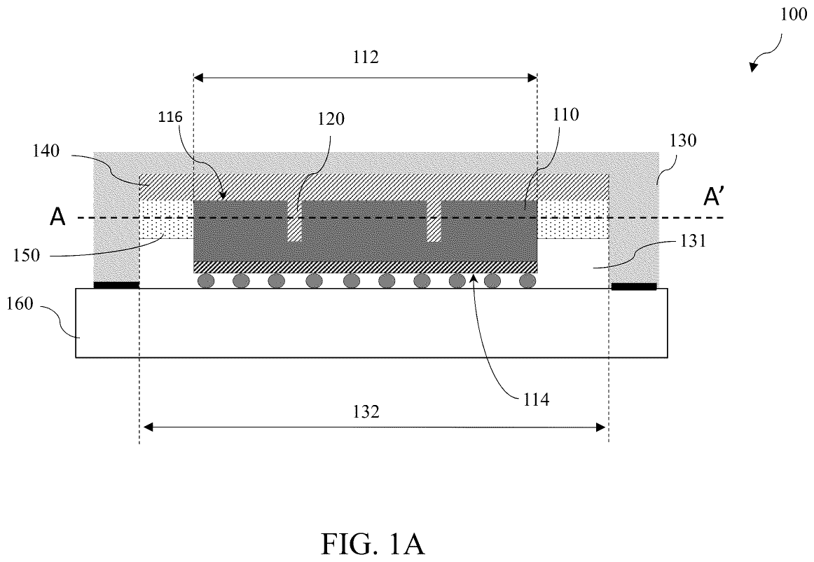

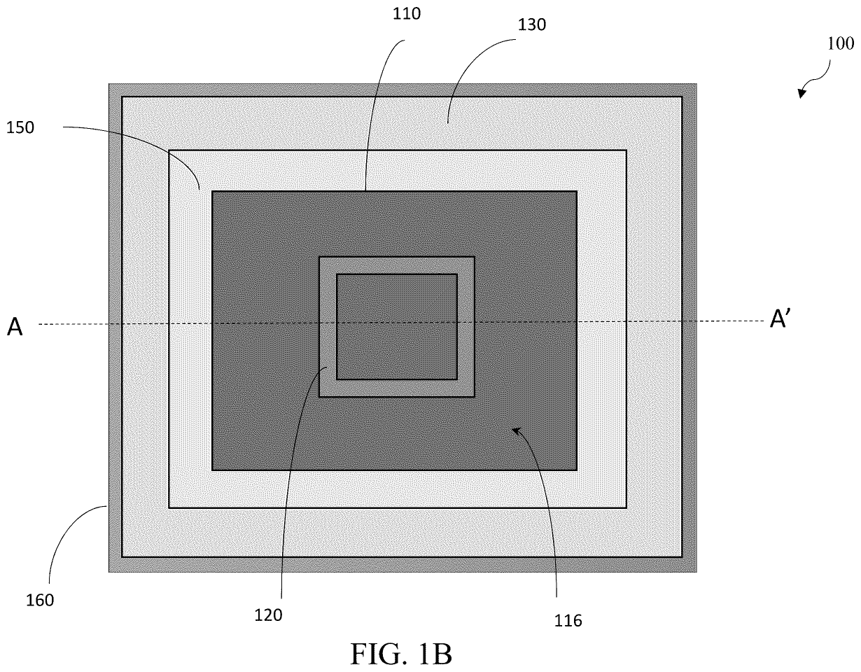

FIG. 1A shows a cross-section of an exemplary electronic assembly 100 according to an aspect of the present disclosure. FIG. 1B shows a top view of the exemplary electronic assembly 100 according to an aspect of the present disclosure. FIG. 1A shows a cross-section view along the section line A-A′ shown in FIG. 1B. According to various embodiments, the electronic assembly includes a first die 110 having a first footprint 112. The first die 110 includes first and second opposing surfaces 114 and 116. The first die 110 may include at least one first trench 120 extending away from the second surface 116. The at least one first trench 120 may extend partially through the first die 110 from the second surface 116. A stiffener 130 including a cavity 131 having a second footprint 132 may extend over the first die 110. The second footprint 132 may be greater than the first footprint 112. The stiffener may be formed of a conductive material. The stiffener may be electrically and thermally conductive. According to various embodiments, the stiffener may include a metal layer, such as an aluminium layer or a stainless steel layer, in a non-limiting example.

A thermally conductive layer 140 may extend across the second footprint 132 in between the second surface 116 of the first die 110 and the stiffener 130. The conductive layer 140 at least partially fills the at least one first trench 120. According to various embodiments, the conductive layer may be a liquid metal. For example, the liquid metal may be metal alloy composites of at least one of tin, indium, gallium, francium, cesium, and rubidium.

A dielectric layer 150 may be positioned in the cavity 131 over the conductive layer 140 and around the first die 110. Said differently, the dielectric layer 150 may extend around the first footprint 112 over the conductive layer 140. The dielectric layer 150 may hold the conductive layer 140 intact to the stiffener 130. The dielectric layer 150 may be an insulator layer. For example, the dielectric layer 150 may be an epoxy polymer layer, a polyimide layer, a mold compound layer, or a silicone layer.

The first die 110 may be coupled to a substrate 160 at the first surface 114. In other words, the first surface 114 of the first die may face the substrate 160. The stiffener 130 may be attached to the substrate 160.

As illustrated in FIG. 1B, the first die 110 may include one first trench 120 in the first die 110. For example, the first trench 120 may be configured to be a continuous rectangular-shaped ring as shown. However, it should be understood that a present trench may have various configurations, such as discontinous or isolated trenches, as long as the trenches may have a depth to partially contain or be filled with material of the conductive layer 140.

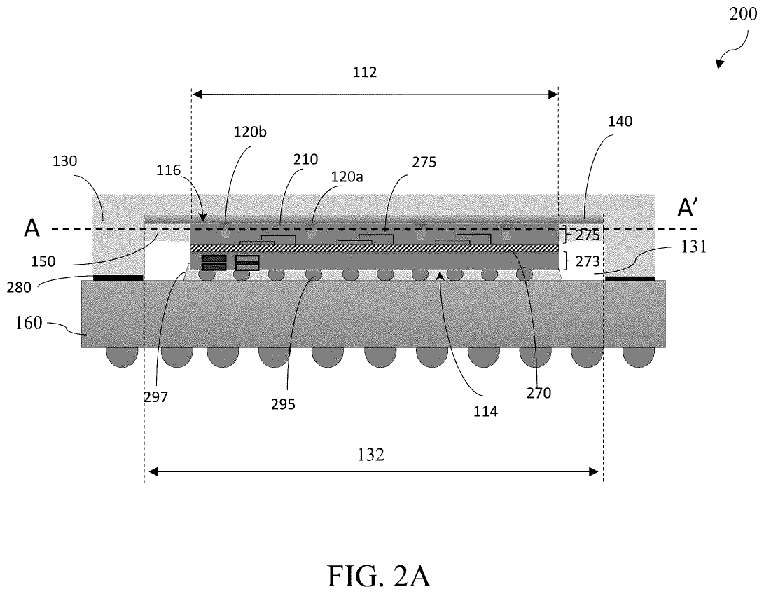

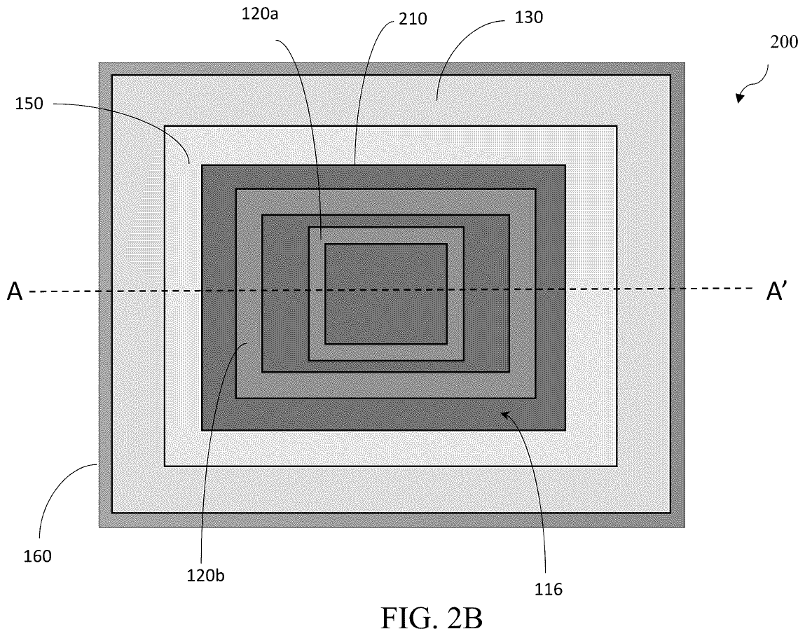

FIGS. 2A and 2B show cross-section and top views, respectively, of another exemplary electronic assembly 200 according to an aspect of the present disclosure. FIG. 2A shows a cross-section view along the section line A-A′ shown in FIG. 2B. The electronic assembly 200 includes an integrated thermally conductive trench cooling feature for improved device thermal management and electrical performance. The electronic assembly 200 may include a first die 210 having a first footprint 112. In a non-limiting example, the first die 210 may include a central processing unit (CPU). The first die 210 includes first and second opposing surfaces 114 and 116. The first die 210 may be coupled to a substrate 160 at the first surface 114.

As illustrated, the first die 210 includes a plurality of first trenches 120a and 120b extending away from the second surface 116 of the first die 210. The plurality of first trenches 120a and 120b may extend a pre-determined depth into the first die 210. The first die 210, for example, may include an active layer 270 (e.g., a transistor layer) between the first surface 114 and the second surface 116 of the first die 210. In an aspect, a first metal redistribution layer (RDL) 273 may be arranged on a first side of the die and adjacent to the active layer 270. The first metal redistribution layer (RDL) 273 may include components of a power delivery network (PDN). In an aspect, a second metal redistribution layer 275 may be arranged on a second side of the die, adjacent to the active layer 270 and opposite to the first RDL 273. The second metal redistribution layer 275, for example, may be a signal routing layer. According to various embodiments, the plurality of first trenches 120a and 120b may extend through at least a portion of the second RDL 275 adjacent to the active layer 270.

The electronic assembly 200 may include a stiffener 130 coupled to the substrate 160 and the second surface 116 of the first die 210. The stiffener 130 and the substrate 160 may be held together by an adhesive layer 280. The adhesive layer 280, for example, may be non-conductive adhesive, such as but not limited to, an epoxy polymer, a polyimide, a polyamide, a polyurethane, an acrylic polymer, or a polyester. Alternatively, the adhesive layer 280 may be a conductive adhesive so as to facilitate coupling the stiffener 130 to a reference voltage. The adhesive layer 280, for example, may be formed of an anisotropic conductive film (ACF) with composites of conductive (e.g., silver, nickel, copper or graphite) and adhesive (e.g., epoxy resin) elements. In another aspect, the conductive adhesive may include a solder (e.g., tin-silver alloy) layer. The stiffener 130 may include a cavity 131 having a second footprint 132 greater than the first footprint 112. The electronic assembly 200 may include a thermally conductive layer 140 extending across the second footprint 132 of the cavity 131 of the stiffener 130. The conductive layer 140 may extend across the second footprint 132 between the second surface 116 of the first die 210 and the stiffener 130. According to various embodiments, the plurality of first trenches 120a and 120b may be at least partially filled by the conductive layer 140 to facilitate thermal dissipation away from the active layer 270 of the die. The conductive layer 140, for example, may be a liquid metal In some embodiments, the plurality of first trenches 120a and 120b may be completely filled by the conductive layer 140.

In an aspect, the plurality of first trenches 120a and 120b may be configured on or adjacent localized thermal hot spots within the first die 210. Providing the plurality of first trenches 120a and 120b which extend through at least a portion of the second RDL 275 and filled with the thermally conductive layer 140 may facilitate heat transfer from thermal hot spots in the die 210. The electronic assembly 200 may include a dielectric layer 150 extending around the first footprint 112 and over the conductive layer 140. The dielectric layer 150, for example, may be an epoxy polymer layer, a polyimide layer, a mold compound layer, or a silicone layer. The dielectric layer 150 may hold the die in place within the cavity 131 of the stiffener 130. For example, the dielectric layer 150 may be thermally cured to form a rigid structure to provide mechanical support to the first die 210 in the electronic assembly 200.

As illustrated in FIG. 2B, the first die 210 may include two first trenches 120a and 120b in the first die 210. For example, each of the first trenches 120a and 120b may be configured to be a continuous ring. However, it should be understood that present trenches may have various configurations, such as discontinous or isolated trenches, as long as the trenches may have a depth to partially contain or be filled with material of the conductive layer 140.

According to various embodiments, the plurality of first trenches may include a first inner ring trench 120a with a first inner trench footprint and a first outer ring trench 120b with a first outer trench footprint. The first outer trench footprint may be greater than the first inner trench footprint.

The plurality of first trenches may be coupled to or associated with a reference voltage, such as a ground reference voltage (Vss) for example, through the stiffener 130 and the substrate 160 to facilitate electromagnetic shielding from undesired coupling noises and/or energy from surrounding signal transmission, such as from radio frequency (RF) transmission and/or to facilitate current return path. In an aspect, the circuitry in the first die 210 adjacent the plurality of first trenches 120a and 120b may be shielded from undesired electromagnetic interference (EMI).

Referring back to FIG. 2A, the first die 210 may be bonded to the substrate 160 by solder bumps 295. The solder bumps 295 may provide coupling between the first die 210 and the substrate 160. The solder bumps 295 may be configured to facilitate power delivery for the first die 210. The electronic assembly 200 may further include an underfill 297 surrounding the solder bumps 295 and space between the first die 210 and the substrate 160. The underfill 297, for example, may be an epoxy layer. The underfill 297 may be a non-flow underfill. Although not shown, it should be understood that other components/devices may be provided to complete the electronic assembly 200.

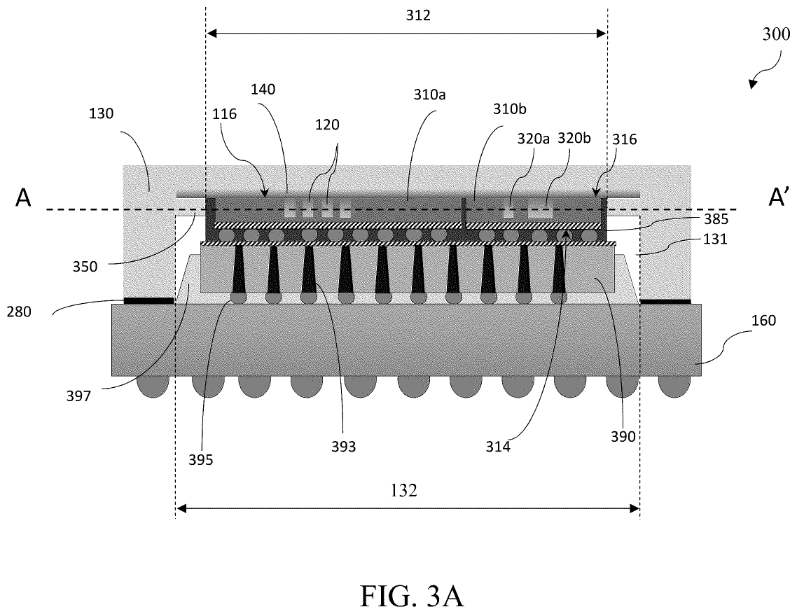

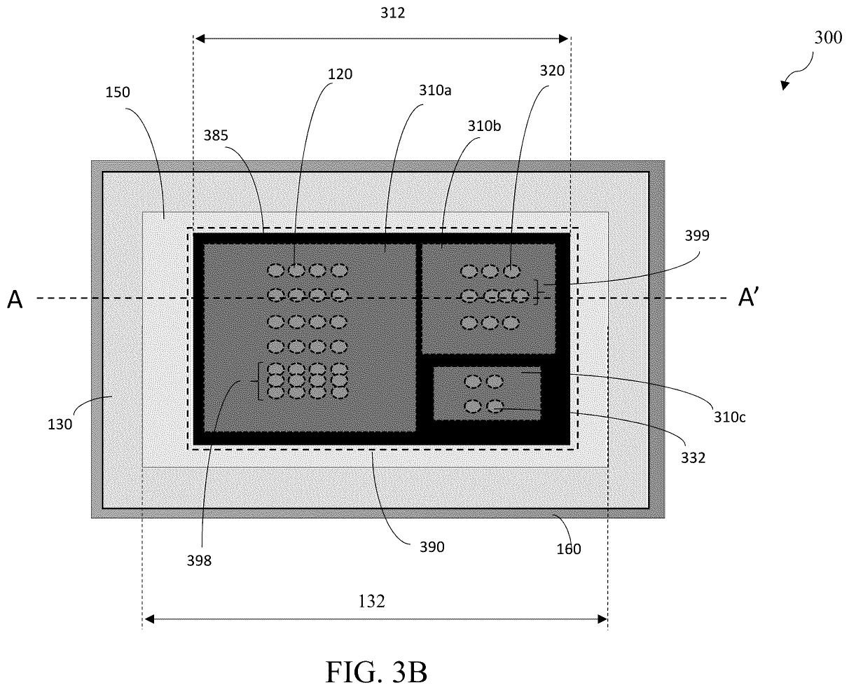

FIGS. 3A and 3B show cross-section and top views, respectively, of an exemplary electronic assembly 300 according to an aspect of the present disclosure. FIG. 3A shows a cross-section view along the section line A-A′ shown in FIG. 3B. The electronic assembly 300 is similar as that shown and described in FIGS. 1A-1B and FIG. 2A-2B. As such, common elements may not be described or described in detail.

The electronic assembly 300 may include a first die or chip 310a and a second die or chip 310b adjacent to the first die 310a. The dies may be arranged side by side. The second die 310b may include first and second opposing surfaces 314 and 316. The second die 310b may be coupled to the substrate 160 at the first surface 314 of the second die 310b.

According to various embodiments, the first die 310a may include a plurality of first trenches 120. The plurality of first trenches 120 may be in the form of columns. Referring to the first die 310a in FIG. 3B, the plurality of first trenches 120 may be isolated columns or pillars. According to various embodiments, the plurality of first trenches 120 may include multiple overlapped columns. For example, the plurality of first trenches 120 may include multiple overlapped columns in a region or section 398 of the first die 310a. Similarly, the second die 310b may include a plurality of second trenches 320a and 320b extending away from the second surface 316 and into a portion of the second die 310b. For example, the plurality of second trenches may include overlapped columns in a region or section 399 of the second die 310b. The plurality of first trenches 120 and the plurality of second trenches 320 may each be at least partially filled with material of the thermally conductive layer 140. Accordingly, the plurality of first trenches 120 and the plurality of second trenches 320 at least partially filled with the conductive layer 140 may form an integrated thermally conductive trench cooling feature of the electronic assembly 300. The overlapping columns may form a greater area or volume for the thermally conductive trench cooling feature for optimized performance. Referring to FIG. 3A, the trench 320b may be wider than the trench 320a of the second die 310b due to the overlapping columns described above.

According to various embodiments, the electronic assembly 300 may further include a third die 330c, as illustrated in FIG. 3B. The third die 330c may include a plurality of third trenches 332, each being at least partially filled with material of the conductive layer 140 described with respect to FIG. 3A. As illustrated in FIG. 3B, each of the first die 310a, second die 310b, and third die 310c may include respective trenches which are at least partially filled with material of the conductive layer 140. The plurality of first trenches 120, the plurality of second trenches 320 and the plurality of third trenches 332, each at least partially filled with the conductive layer 140 may form an integrated thermally conductive trench cooling feature of the electronic assembly 300. Although not shown, it should be understood that other components/devices may be provided to complete the electronic assembly 300.

According to various embodiments, the first, second and third dies 310a, 310b and 310c may be encapsulated within a mold layer 385 having a first footprint 312. The first footprint 312 may be less than a second footprint 132 of the cavity 131 of the stiffener 130. In a non-limiting example, the mold layer 385 may be an epoxy polymer and silica composite layer.

In an aspect, the conductive layer 140 may extend across the second footprint 312 in between the second surface 116 of the first die 310a, the second surface 316 of the second die 310b and the stiffener 130, as illustrated in FIG. 3A, to facilitate thermal dissipation, for example, from the active layers of the first and second dies 310a and 310b. It is understood that the conductive layer 140 may also extend across the second footprint 312 in between a second surface of the third die 310c and the stiffener 130 (not shown in FIG. 3A).

The electronic assembly 300 may include a dielectric layer 350 extending around the first footprint 312 and over the conductive layer 140. The dielectric layer 350, for example, may be an epoxy polymer layer, a polyimide layer, a mold compound layer, or a silicone layer. In a non-limiting example, the first die 310a may include a central processing unit (CPU). For example, the second die 310b may include a graphic processing unit (GPU), a neural processing unit (NPU), a deep learning processor (DLP), a system-on-chip (SOC), a memory device, a field programmable gate array (FGPA), a platform controller hub (PCH) chipset or an I/O tile. In an aspect, the substrate 160 includes a silicon interposer, a multi-layer organic package, or a printed circuit board (PCB).

The electronic assembly 300 may further include an interposer 390 arranged between the mold layer 385 and the substrate 160. The interposer 390, for example, may be a silicon interposer. The interposer 390 may include through silicon vias (TSVs) 393 extending between top and bottom surfaces of the interposer. The through silicon vias 393 may extend through a depth of the interposer 390, for example, to facilitate power delivery from the substrate 160 to the first and second dies 310a and 310b and/or signal transmission.

The electronic assembly 300 may include solder bumps 395 for bonding the interposer 390 to the substrate 160. The solder bumps 395 may couple the dies 310a and 310b to the substrate 160 (e.g., via the interposer 390). An underfill 397 may surround the interposer 390. The underfill 397, for example, may be an epoxy layer. The underfill 397 may be a non-flow underfill.

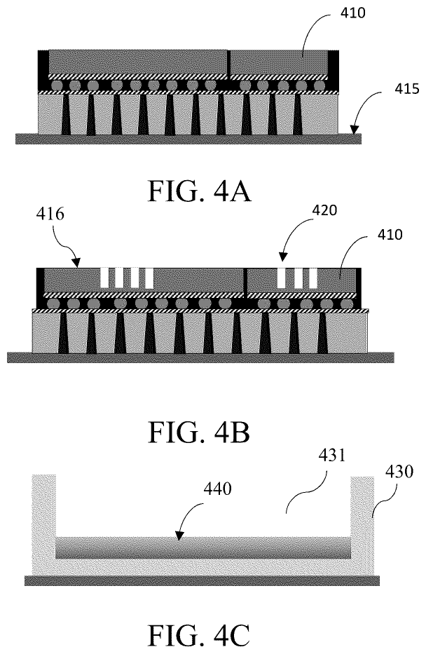

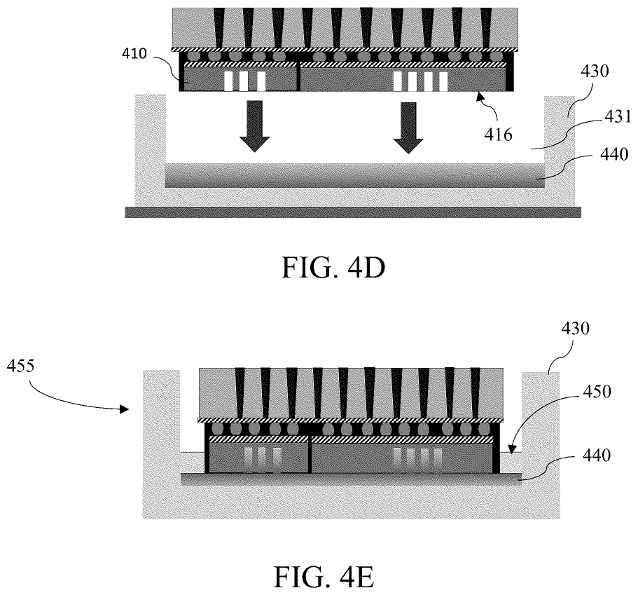

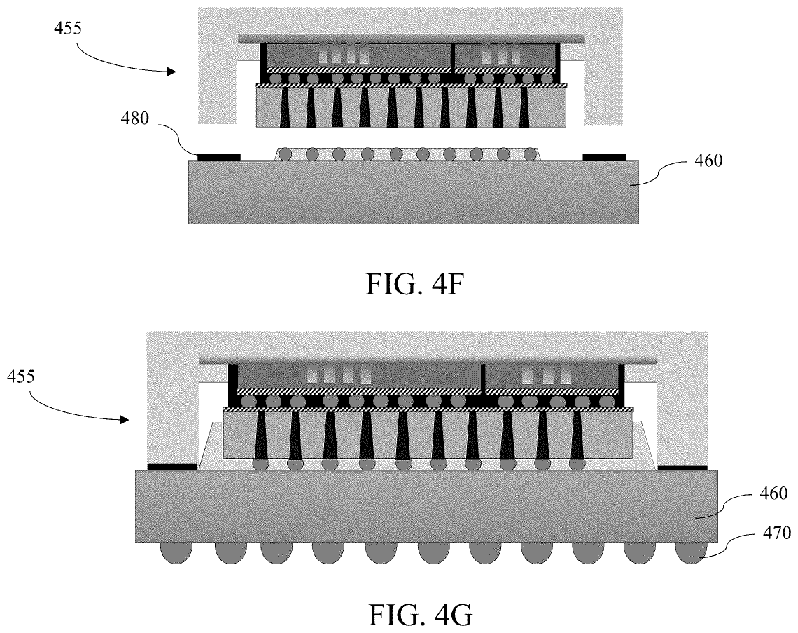

FIGS. 4A through 4G show exemplary method steps for forming an integrated thermally conductive trench cooling feature in an electronic or semiconductor assembly, according to an aspect of the present disclosure. The thermally conductive trench cooling feature may be provided for enhanced thermal performance and device miniaturization. In a non-limiting example, the electronic assembly may be a 2.5D stacked integrated circuit package with liquid metal trenches.

As shown in FIG. 4A, an incoming stacked chiplet (e.g., chiplets stacked side by side) or mold containing dies 410 may be attached to a carrier 415, for example, by lamination or hot press processing. As shown in FIG. 4B, a plurality of trenches 420 may be formed in the dies 410. The plurality of trenches 420 may be formed to extend from a second surface 416 of the dies. For example, portions of silicon substrate may be removed from the dies 410 so as to form the trenches. In other embodiments, portions of a redistribution layer (RDL) may be removed from the dies so as to form the trenches. The trenches may be formed, for example, by mechanical drilling, a chemical or a laser etching process. Other techniques may also be used to form the trenches in the dies.

A liquid metal may be deposited within a cavity 431 of a stiffener 430 to form a conductive layer 440, as shown in FIG. 4C. The liquid metal may be deposited, for example, by compression, transfer, injection, or a dispensing process.

Referring to FIG. 4D, the stacked chiplets or mold containing the dies 410 may be inverted. The stacked chiplets or mold containing the dies 410 may be positioned with the second surface 416 of the dies facing the liquid metal. The stacked chiplets or mold containing the dies 410 may be moved into the cavity 431 of the stiffener 430 to enable the liquid metal to at least partially fill the trenches in the dies 410. The chiplets or mold containing the dies 410 may be positioned in the cavity 431 of the stiffener 430, for example, by a vacuum pick and place process. The chiplets or mold containing the dies 410 may be coupled to the stiffener 430. The stacked chiplets or mold containing the dies 410 may be mechanically coupled (e.g., in contact) with the stiffener 430 through the conductive layer 440.

As shown in FIG. 4E, a dielectric layer 450 may be formed on the conductive layer 440. The dielectric layer 450, for example, may be an epoxy resin. The epoxy resin may be dispensed on the conductive layer 440, followed by a curing process (e.g., epoxy curing). The stacked chiplets or mold containing the dies 410 and the stiffener 430 may form an integrated chiplet and stiffener module 455.

Referring to FIG. 4F, an adhesive layer 480 may be applied to a package substrate 460 for attaching/bonding the integrated chiplet and stiffener module 455 to the package substrate 460. An underfill and solder bumps may be provided on the substrate 460. The integrated chiplet and stiffener module 455 may be inverted and positioned to be attached to the package substrate 460. The integrated chiplet and stiffener module 455 may be attached to the package substrate 460, for example, by solder reflow (e.g., first solder reflow process), thermal compression process, etc.

Referring to FIG. 4G, solder balls 470 may be attached to the package substrate 460, for example, by surface mounting, solder reflow process (e.g., second solder reflow process with different temperature and duration from the first solder reflow process), etc.

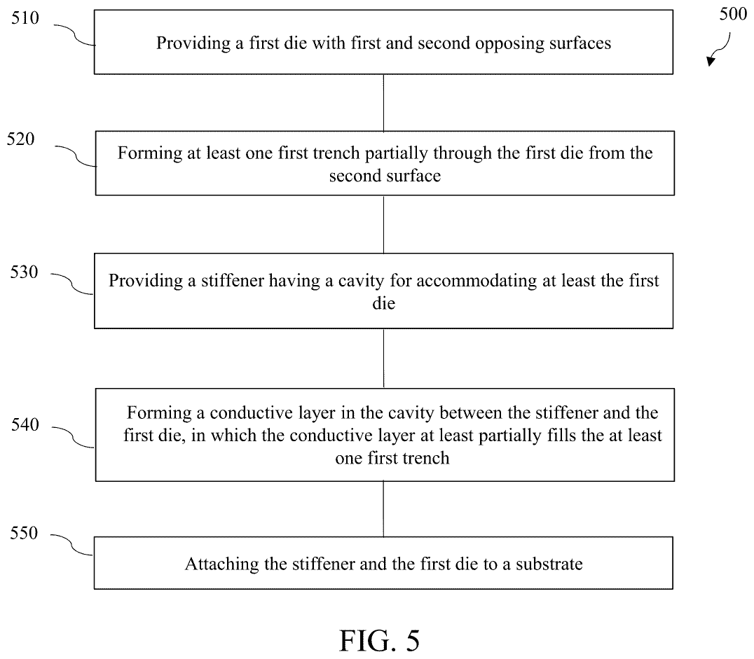

FIG. 5 shows a simplified flow diagram for an exemplary method according to an aspect of the present disclosure.

At 510, a first die with first and second opposing surfaces may be provided.

At 520, at least one first trench may be formed at least partially through the first die from the second surface.

At 530, a stiffener having a cavity for accommodating at least the first die may be provided.

At 540, a conductive layer may be formed in the cavity between the stiffener and the first die, in which the conductive layer at least partially fills the at least one first trench.

At 550, the stiffener and the first die may be attached to a substrate, forming an electronic assembly.

To more readily understand and put into practical effect the present cooling feature of the electronic assembly, they will now be described by way of examples. For the sake of brevity, duplicate descriptions of features and properties may be omitted.

### EXAMPLES

Example 1 provides an electronic assembly including a substrate, a first die with first and second opposing surfaces, in which the first die is coupled to the substrate at the first surface, at least one first trench extending partially through the first die from the second surface, a stiffener attached to the substrate, the stiffener having a cavity that accommodates the first die, in which the second surface of the first die faces the stiffener, and a thermally conductive layer positioned in the cavity between the stiffener and the first die and at least partially fills the at least one first trench.

Example 2 may include the electronic assembly of example 1 and/or any other example disclosed herein, for which the first die has a first footprint and the cavity of the stiffener has a second footprint, and in which the conductive layer extends across the second footprint between the stiffener and the second surface of the first die.

Example 3 may include the electronic assembly of example 1 and/or any other example disclosed herein, for which the conductive layer is a liquid metal.

Example 4 may include the electronic assembly of example 3 and/or any other example disclosed herein, for which the liquid metal includes metal alloy composites of at least one of tin, indium, gallium, francium, cesium, and rubidium.

Example 5 may include the electronic assembly of example 1 and/or any other example disclosed herein, further including a dielectric layer positioned in the cavity over the conductive layer and around the first die, for which the dielectric layer holds the conductive layer intact to the stiffener.

Example 6 may include the electronic assembly of example 5 and/or any other example disclosed herein, for which the dielectric layer includes an epoxy polymer layer, a polyimide layer, a mold compound layer, or a silicone layer.

Example 7 may include the electronic assembly of example 1 and/or any other example disclosed herein, for which the stiffener is formed of a conductive material.

Example 8 may include the electronic assembly of example 1 and/or any other example disclosed herein, for which the stiffener and the conductive layer is coupled to a reference voltage.

Example 9 may include the electronic assembly of example 1 and/or any other example disclosed herein, for which the at least one first trench includes a plurality of columns.

Example 10 may include the electronic assembly of example 1 and/or any other example disclosed herein, for which the at least one first trench includes a first inner ring trench with a first inner trench footprint and a first outer ring trench with a first outer trench footprint, the first outer trench footprint being greater than the first inner trench footprint.

Example 11 may include the electronic assembly of example 1 and/or any other example disclosed herein, further including a second die adjacent to the first die, the second die includes first and second opposing surfaces, and at least one second trench extending partially through the second die from the second surface of the second die.

Example 12 may include the electronic assembly of example 11 and/or any other example disclosed herein, for which the first and second dies are encapsulated within a mold layer with a first footprint, the cavity of the stiffener has a second footprint, and for which the conductive layer extends across the second footprint between the stiffener and the second surface of the first die and the second surface of the second die, and the conductive layer further at least partially fills the at least one second trench.

Example 13 may include the electronic assembly of example 12 and/or any other example disclosed herein, further including a dielectric layer positioned in the cavity over the conductive layer and around the mold layer, for which the dielectric layer holds the conductive layer intact to the stiffener.

Example 14 may include the electronic assembly of example 11 and/or any other example disclosed herein, for which first die includes a central processing unit (CPU).

Example 15 may include the electronic assembly of example 14 and/or any other example disclosed herein, for which the second die includes a graphic processing unit (GPU), a neural processing unit (NPU), a deep learning processor (DLP), a system-on-chip (SOC), a memory device, a field programmable gate array (FGPA) or an I/O tile.

Example 16 provides a method including providing a first die with first and second opposing surfaces, forming at least one first trench partially through the first die from the second surface, providing a stiffener having a cavity for accommodating at least the first die, and forming a conductive layer in the cavity between the stiffener and the first die such that the conductive layer at least partially fills the at least one first trench, and attaching the stiffener and the first die to a substrate, forming an electronic assembly.

Example 17 may include the method of example 16 and/or any other example disclosed herein, for which forming the conductive layer between the stiffener and the first die includes depositing a conductive material into the cavity of the stiffener, positioning the first die with the second surface of the first die facing the conductive material, and moving the first die into the cavity of the stiffener such that the conductive material at least partially fills the at least one first trench.

Example 18 may include the method of example 17 and/or any other example disclosed herein, for which the conductive material is a liquid metal.

Example 19 may include the method of example 16 and/or any other example disclosed herein, further including forming a dielectric layer over the conductive layer and around the first die in the cavity.

Example 20 may include the method of example 16 and/or any other example disclosed herein, further including providing a second die adjacent to the first die, the first die and the second die being encapsulated in a mold layer.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

The terms “and” and “or” herein may be understood to mean “and/or” as including either or both of two stated possibilities.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. An electronic assembly, comprising:
a substrate;
a first die with first and second opposing surfaces, wherein the first die is coupled to the substrate at the first surface;
at least one first trench extending partially through the first die from the second surface;
a stiffener attached to the substrate, the stiffener having a cavity that accommodates the first die, wherein the second surface of the first die faces the stiffener; and
a thermally conductive layer positioned in the cavity between the stiffener and the first die and at least partially filling the at least one first trench.

2. The electronic assembly of claim 1, wherein the first die has a first footprint and the cavity of the stiffener has a second footprint, and wherein the conductive layer extends across the second footprint between the stiffener and the second surface of the first die.

3. The electronic assembly of claim 1, wherein the conductive layer is a liquid metal.

4. The electronic assembly of claim 3, wherein the liquid metal comprises metal alloy composites of at least one of tin, indium, gallium, francium, cesium, and rubidium.

5. The electronic assembly of claim 1, further comprising a dielectric layer positioned in the cavity over the conductive layer and around the first die, wherein the dielectric layer holds the conductive layer intact to the stiffener.

6. The electronic assembly of claim 5, wherein the dielectric layer comprises an epoxy polymer layer, a polyimide layer, a mold compound layer, or a silicone layer.

7. The electronic assembly of claim 1, wherein the stiffener is formed of a conductive material.

8. The electronic assembly of claim 1, wherein the stiffener and the conductive layer is coupled to a reference voltage.

9. The electronic assembly of claim 1, wherein the at least one first trench comprises a plurality of columns.

10. The electronic assembly of claim 1, wherein the at least one first trench comprises a first inner ring trench with a first inner trench footprint and a first outer ring trench with a first outer trench footprint, the first outer trench footprint being greater than the first inner trench footprint.

11. The electronic assembly of claim 1, further comprising:
a second die adjacent to the first die, the second die includes first and second opposing surfaces; and
at least one second trench extending partially through the second die from the second surface of the second die.

12. The electronic assembly of claim 11, wherein the first and second dies are encapsulated within a mold layer with a first footprint, the cavity of the stiffener has a second footprint, and wherein the conductive layer extends across the second footprint between the stiffener and the second surface of the first die and the second surface of the second die, and wherein the conductive layer further at least partially fills the at least one second trench.

13. The electronic assembly of claim 12, further comprising a dielectric layer positioned in the cavity over the conductive layer and around the mold layer, wherein the dielectric layer holds the conductive layer intact to the stiffener.

14. The electronic assembly of claim 11, wherein the first die comprises a central processing unit (CPU).

15. The electronic assembly of claim 14, wherein the second die comprises a graphic processing unit (GPU), a neural processing unit (NPU), a deep learning processor (DLP), a system-on-chip (SOC), a memory device, a field programmable gate array (FGPA) or an I/O tile.

16. A method, comprising:
providing a first die with first and second opposing surfaces;
forming at least one first trench partially through the first die from the second surface;
providing a stiffener having a cavity for accommodating at least the first die; and
forming a conductive layer in the cavity between the stiffener and the first die, wherein the conductive layer at least partially fills the at least one first trench; and
attaching the stiffener and the first die to a substrate, forming an electronic assembly.

17. The method of claim 16, wherein forming the conductive layer between the stiffener and the first die comprises:
depositing a conductive material into the cavity of the stiffener; and
positioning the first die with the second surface of the first die facing the conductive material; and
moving the first die into the cavity of the stiffener such that the conductive material at least partially fills the at least one first trench.

18. The method of claim 17, wherein the conductive material is a liquid metal.

19. The method of claim 16, further comprising forming a dielectric layer over the conductive layer and around the first die in the cavity.

20. The method of claim 16, further comprising providing a second die adjacent to the first die, the first die and the second die being encapsulated in a mold layer.
